(19) United States
(12) Patent Application Publication
(10) Pub. No.: US 2024/0055453 A1
(43) Pub. Date: Feb. 15, 2024

(54) SENSOR PACKAGE STRUCTURE

(71) Applicant: TONG HSING ELECTRONIC INDUSTRIES, LTD., Taipei City (TW)

(72) Inventors: JUI-HUNG HSU, Hsin-Chu County (TW); CHIEN-CHEN LEE, Hsin-Chu County (TW); LI-CHUN HUNG, Hsin-Chu County (TW)

(21) Appl. No.: 17/965,742

(22) Filed: Oct. 13, 2022

(30) Foreign Application Priority Data
Aug. 15, 2022 (TW) 111130519

(51) Int. Cl. H01L 27/146

(52) U.S. Cl. CPC H01L 27/14623; H01L 27/14618; H01L 27/14636

(57) ABSTRACT

A sensor package structure is provided and includes a substrate, a sensor chip mounted on the substrate, a supporting layer being ring-shaped and disposed on the sensor chip, a light-permeable layer, and a grooved shielding layer that is ring-shaped and that is disposed on a lower surface of the light-permeable layer. The grooved shielding layer includes an inner barrier and an outer barrier respectively located at two opposite sides of the supporting layer. An inner edge of the inner barrier has an opening directly located above a sensing region of the sensor chip. The inner barrier, the outer barrier, and a part of the lower surface of the light-permeable layer jointly define a ring-shaped groove. The part of the lower surface of the light-permeable layer is disposed on the supporting layer, so that a part of the supporting layer is arranged in the ring-shaped groove.

### CROSS-REFERENCE TO RELATED PATENT APPLICATION

This application claims the benefit of priority to Taiwan Patent Application No. 111130519, filed on Aug. 15, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a sensor package structure, and more particularly to a sensor package structure having a grooved shielding layer.

### BACKGROUND OF THE DISCLOSURE

In a conventional sensor package structure, a glass board is arranged above a sensor chip through a glue layer that surrounds a sensing region of the sensor chip. However, light passing through the glass board may be partially reflected by the glue layer to affect the sensing region of the sensor chip (e.g., by generating a glare phenomenon). Moreover, in the solidifying process of the glue layer of the conventional sensor package structure, air trapped inside the glue layer pushes outwardly against the glue layer after being heated, so that the glue layer is easily deformed or has an offset.

### SUMMARY OF THE DISCLOSURE

In response to the above-referenced technical inadequacies, the present disclosure provides a sensor package structure to effectively improve on the issues associated with conventional sensor package structures.

In one aspect, the present disclosure provides a sensor package structure, which includes a substrate, a sensor chip, a supporting layer, a light-permeable layer, and a grooved shielding layer. The sensor chip is disposed on the substrate along a predetermined direction and is electrically coupled to the substrate. A top surface of the sensor chip includes a sensing region and a carrying region that surrounds the sensing region. The supporting layer is ring-shaped and is disposed on the carrying region of the sensor chip. The light-permeable layer has an upper surface and a lower surface that is opposite to the upper surface. The light-permeable layer is arranged above the sensor chip through the supporting layer, and the sensing region faces toward the light-permeable layer. The grooved shielding layer is ring-shaped. The grooved shielding layer is disposed on the lower surface of the light-permeable layer for blocking a visible light from passing therethrough. The grooved shielding layer includes an inner barrier located at an inner side of the supporting layer, an outer barrier located at an outer side of the supporting layer, and a connection segment that is connected to the inner barrier and the outer barrier so as to jointly form a ring-shaped groove. The grooved shielding layer is disposed on the supporting layer through the connection segment, so that a part of the supporting layer is arranged in the ring-shaped groove. Moreover, an inner edge of the inner barrier has an opening directly located above the sensing region. The grooved shielding layer, the light-permeable layer, the supporting layer, and the sensor chip jointly define an enclosed space, and the inner barrier is arranged in the enclosed space.

In another aspect, the present disclosure provides a sensor package structure, which includes a substrate, a sensor chip, a supporting layer, a light-permeable layer, and a grooved shielding layer. The sensor chip is disposed on the substrate along a predetermined direction and is electrically coupled to the substrate. A top surface of the sensor chip includes a sensing region and a carrying region that surrounds the sensing region. The supporting layer has a ring shape and is disposed on the carrying region of the sensor chip. The light-permeable layer has an upper surface and a lower surface that is opposite to the upper surface. The light-permeable layer is arranged above the sensor chip through the supporting layer, and the sensing region faces toward the light-permeable layer. The grooved shielding layer is ring-shaped. The grooved shielding layer is disposed on the lower surface of the light-permeable layer for blocking a visible light from passing therethrough. The grooved shielding layer includes an inner barrier located at an inner side of the supporting layer and an outer barrier that is located at an outer side of the supporting layer. The inner barrier, the outer barrier, and a part of the lower surface of the light-permeable layer jointly form a ring-shaped groove. The light-permeable layer is disposed on the supporting layer through the part of the lower surface thereof, so that a part of the supporting layer is arranged in the ring-shaped groove. Moreover, an inner edge of the inner barrier has an opening directly located above the sensing region. The light-permeable layer, the supporting layer, and the sensor chip jointly define an enclosed space, and the inner barrier is arranged in the enclosed space.

Therefore, the sensor package structure of the present disclosure is provided with the structural cooperation between the supporting layer and the grooved shielding layer so as to simultaneously have a plurality of technical effects, such as the grooved shielding layer being capable of blocking a visible light from passing therethrough so as to reduce the glare phenomenon that is generated by the visible light reflected from the supporting layer, and the grooved shielding layer being capable of limiting an offset of the supporting layer by blocking the supporting layer from being outwardly deformed any further, thereby avoiding a peeling issue of the light-permeable layer.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a perspective view of a sensor package structure according to a first embodiment of the present disclosure;

FIG. 2 is a cross-sectional view taken along line II-II of FIG. 1;

FIG. 3 is an enlarged view of part III of FIG. 2;

FIG. 4 is a schematic view showing a structure of FIG. 3 in another configuration;

FIG. 5 is a perspective view of the sensor package structure according to a second embodiment of the present disclosure;

FIG. 6 is a cross-sectional view taken along line VI-VI of FIG. 5;

FIG. 7 is an enlarged view of part VII of FIG. 6; and

FIG. 8 is a schematic view showing a structure of FIG. 7 in another configuration.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

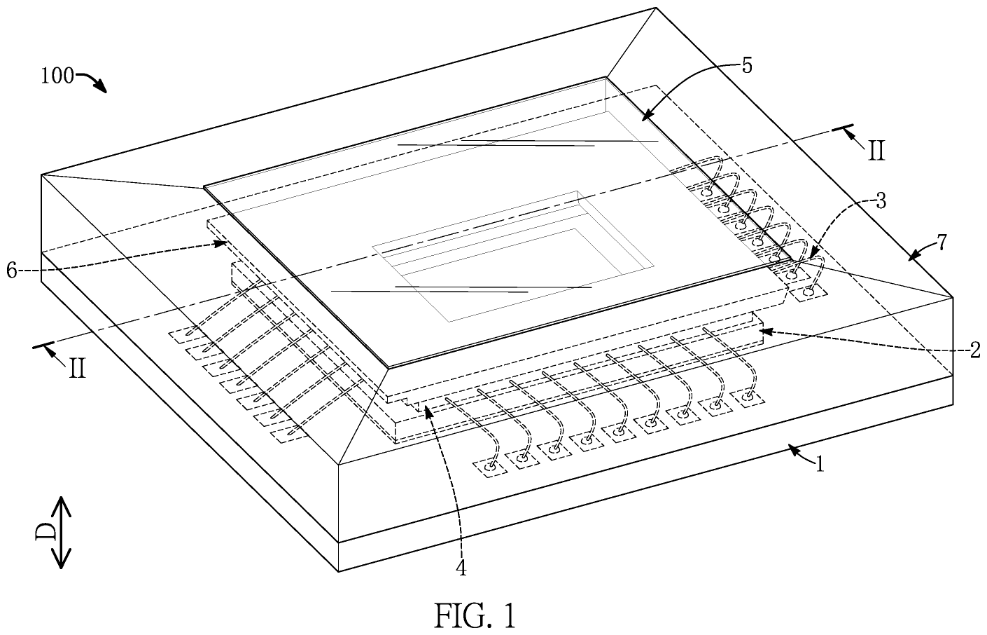

Referring to FIG. 1 to FIG. 4, a first embodiment of the present disclosure provides a sensor package structure 100. In other words, any package structure not encapsulating a sensor chip therein has a structural design different from that of the sensor package structure 100 of the present embodiment (as shown in FIG. 1).

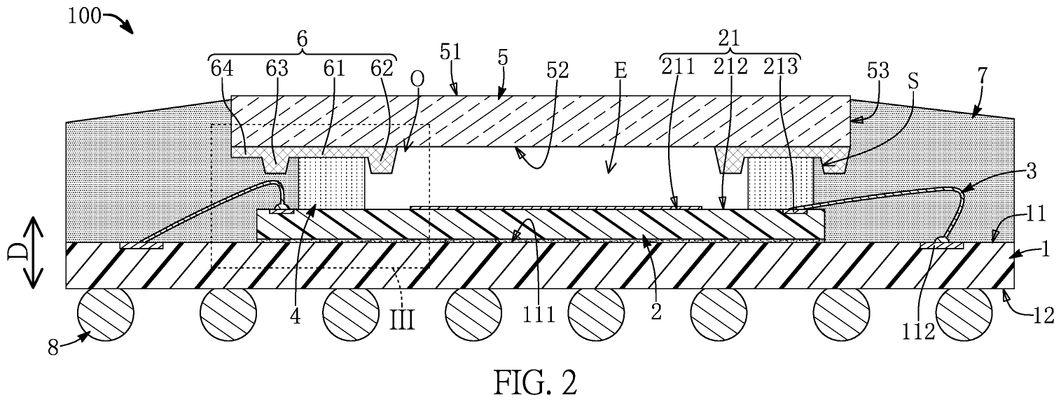

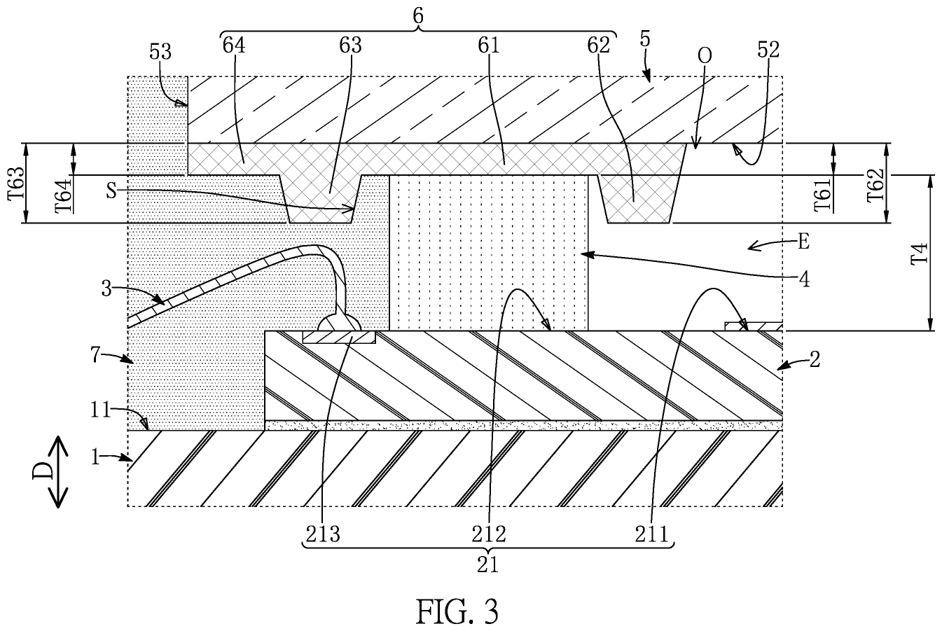

As shown in FIG. 2 and FIG. 3, the sensor package structure 100 includes a substrate 1, a sensor chip 2 disposed on the substrate 1 along a predetermined direction D, a plurality of metal wires 3 electrically coupling the sensor chip 2 and the substrate 1, a supporting layer 4 disposed on the sensor chip 2, a light-permeable layer 5 arranged above the sensor chip 2 through the supporting layer 4, a grooved shielding layer 6 disposed on the light-permeable layer 5, and an encapsulant 7 that is formed on the substrate 1.

Although the sensor package structure 100 in the present embodiment is illustrated as including the above components, the sensor package structure 100 can also be modified according to design requirements. For example, in other embodiments of the present disclosure not shown in the drawings, the sensor package structure 100 can be provided without the metal wires 3, and the sensor chip 2 is fixed onto the substrate 1 in a flip chip manner for electrically coupling the sensor chip 2 to the substrate 1; or, the encapsulant 7 of the sensor package structure 100 can be omitted or can be replaced by other components. The following description describes the structure and connection relationship of each component of the sensor package structure 100 provided by the present embodiment.

The substrate 1 in the present embodiment has a square shape or a rectangular shape, but the present disclosure is not limited thereto. The substrate 1 has an upper board surface 11 and a lower board surface 12 that is opposite to the upper board surface 11. The substrate 1 has a chip bonding region 111 and a plurality of bonding pads 112, the chip bonding region 111 is substantially on a center portion of the upper board surface 11, and the bonding pads 112 are arranged on the upper board surface 11 and outside of the chip bonding region 111 (or the sensor chip 2). The bonding pads 112 in the present embodiment are substantially arranged in a ring shape, but the present disclosure is not limited thereto. For example, in other embodiments of the present disclosure not shown in the drawings, the bonding pads 112 can be arranged in two rows that are respectively located at two opposite sides of the chip bonding region 111.

In addition, the substrate 1 in the present embodiment can be provided with a plurality of solder balls 8 disposed on the lower board surface 12, and the sensor package structure 100 can be mounted onto an electronic component (not shown) through the solder balls 8, thereby electrically coupling the sensor package structure 100 to the electronic component.

The sensor chip 2 in the present embodiment is illustrated as an image sensor chip, but the present disclosure is not limited thereto. The sensor chip 2 is fixed to the chip bonding region 111 of the substrate 1, and the sensor chip 2 is located inboard of the bonding pads 112. Moreover, a top surface 21 of the sensor chip 2 has a sensing region 211, a carrying region 212 (in a ring shape) surrounding the sensing region 211, and a plurality of connection pads 213 that are arranged on the carrying region 212.

The quantity and positions of the connection pads 213 of the sensor chip 2 in the present embodiment respectively correspond to those of the bonding pads 112 of the substrate 1. Moreover, terminals at one end of the metal wires 3 are respectively connected to the bonding pads 112, and terminals at the other end of the metal wires 3 are respectively connected to the connection pads 213, so that the substrate 1 can be electrically coupled to the sensor chip 2 through the metal wires 3.

The supporting layer 4 is ring-shaped and is disposed on the carrying region 212 of the sensor chip 2, and each of the connection pads 213 can be selectively provided to be embedded in the supporting layer 4 or to be located inboard of the supporting layer 4. For example, as shown in the left portion of FIG. 2, at least one of the connection pads 213 and the corresponding metal wire 3 connected thereto are located outside of the supporting layer 4; or, as shown in the right portion of FIG. 2, at least one of the connection pads 213 and a part of the corresponding metal wire 3 connected thereto are embedded in the supporting layer 4.

The light-permeable layer 5 in the present embodiment is illustrated as a flat and transparent glass board, but the present disclosure is not limited thereto. The light-permeable layer 5 includes an upper surface 51, a lower surface 52 opposite to the upper surface 51, and a surrounding lateral surface 53 that is connected to the upper surface 51 and the lower surface 52. The light-permeable layer 5 is disposed above the sensor chip 2 through the supporting layer 4, and the lower surface 52 faces toward the sensing region 211.

The grooved shielding layer 6 has a ring shape and is disposed on the lower surface 52 of the light-permeable layer 5 for blocking a visible light from passing therethrough. The grooved shielding layer 6 in the present embodiment can allow an infrared light having a wavelength greater than 780 nm to pass therethrough, and can block the visible light having a wavelength of 365 nm to 780 nm from passing therethrough, but the present disclosure is not limited thereto.

Specifically, the grooved shielding layer 6 in the present embodiment includes a connection segment 61 having a ring shape, an inner barrier 62 having a ring shape and extending inwardly from the connection segment 61, and an outer barrier 63 that is ring-shaped and that extends outwardly from the connection segment 61. In other words, the connection segment 61 connects the inner barrier 62 and the outer barrier 63 so as to jointly form a ring-shaped groove S.

The grooved shielding layer 6 is disposed on the supporting layer 4 through the connection segment 61, so that a part of the supporting layer 4 is arranged in the ring-shaped groove S. In other words, the connection segment 61 is sandwiched between the light-permeable layer 5 and the supporting layer 4. Accordingly, the grooved shielding layer 6, the light-permeable layer 5, the supporting layer 4, and the sensor chip 2 jointly define an enclosed space E.

Moreover, the inner barrier 62 is located at an inner side of the supporting layer 4 (e.g., the inner barrier 62 is arranged in the enclosed space E), and an inner edge of the inner barrier 62 has an opening O located directly above the sensing region 211. The outer barrier 63 is located at an outer side of the supporting layer 4, and at least part of an edge of the outer barrier 63 can be flush with the surrounding lateral surface 53 of the light-permeable layer 5. In addition, the grooved shielding layer 6 can include an extension segment 64 connected to the outer barrier 63, and an edge of the extension segment 64 is flush with the surrounding lateral surface 53 of the light-permeable layer 5.

It should be noted that in order to enable the grooved shielding layer 6 to have a better anti-glare effect and in order to effectively prevent the supporting layer 4 from being deformed outwardly (or having an offset) due to air in the enclosed space E expanding and pushing the supporting layer 4 outward when heated, the connection segment 61, the inner barrier 62, and the outer barrier 63 are preferably provided with at least part of the following features, but the present disclosure is not limited thereto.

At least one of the inner barrier 62 and the outer barrier 63 has a frustum shape that tapers in the predetermined direction D toward the sensor chip 2, but the present disclosure is not limited thereto. Specifically, along the predetermined direction D, a thickness T61 of the connection segment 61 is within a range from 10% to 80% of a thickness T62 of the inner barrier 62 and is substantially equal to a thickness T64 of the extension segment 64, and the thickness T62 of the inner barrier 62 is within a range from 50% to 300% of a thickness T63 of the outer barrier 63, but the thicknesses can be adjusted or changed according to design requirements.

In other words, the supporting layer 4 has a supporting thickness T4 along the predetermined direction D, the thickness T62 of the inner barrier 62 is preferably within a range from 10% to 30% of the supporting thickness T4, and the thickness T63 of the outer barrier 63 is also within a range from 10% to 30% of the supporting thickness T4.

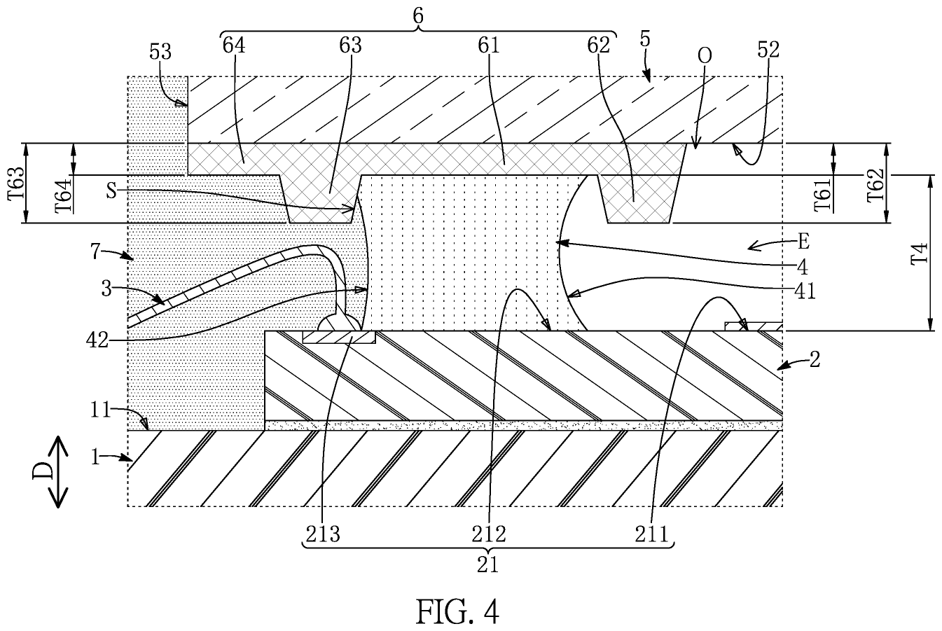

Specifically, as shown in FIG. 4, when the supporting layer 4 is outwardly deformed or has the offset, the outer barrier 63 can be used to limit the offset by blocking the supporting layer 4 from being outwardly deformed any further, so that an area of the inner barrier 62 connected to the supporting layer 4 is less than an area of the outer barrier 63 connected to the supporting layer 4. Moreover, the supporting layer 4 has an inner arced surface 41 and an outer arced surface 42, and a radius of curvature of the inner arced surface 41 is less than a radius of curvature of the outer arced surface 42. A center of curvature of the inner arced surface 41 can be substantially located in the enclosed space E, and a center of curvature of the outer arced surface 42 is located outside of the sensor package structure 100.

As shown in FIG. 2 and FIG. 3, the encapsulant 7 is formed on the upper board surface 11 of the substrate 1, and a lateral edge of the encapsulant 7 is flush with that of the substrate 1. The sensor chip 2, the supporting layer 4, the light-permeable layer 5, and at least part of each of the metal wires 4 are embedded in the encapsulant 7, and at least part of the upper surface 51 of the light-permeable layer 5 (e.g., a part of the upper surface 51 corresponding in position to the opening O) is exposed from the encapsulant 7.

Moreover, the encapsulant 7 is connected to a part of the grooved shielding layer 6; in other words, the outer barrier 63 of the grooved shielding layer 6 is embedded in the encapsulant 7. In addition, a part of the ring-shaped groove S between the supporting layer 4 and the outer barrier 63 is filled with the encapsulant 7, thereby enhancing the connection between the grooved shielding layer 6 and the encapsulant 7.

Specifically, the encapsulant 7 in the present embodiment is formed by solidifying a liquid compound, but the present disclosure is not limited thereto. For example, in other embodiments of the present disclosure not shown in the drawings, the encapsulant 7 can further include a molding compound formed on a top surface of the solidified liquid compound; or, the encapsulant 7 can be a molding compound.

### Second Embodiment

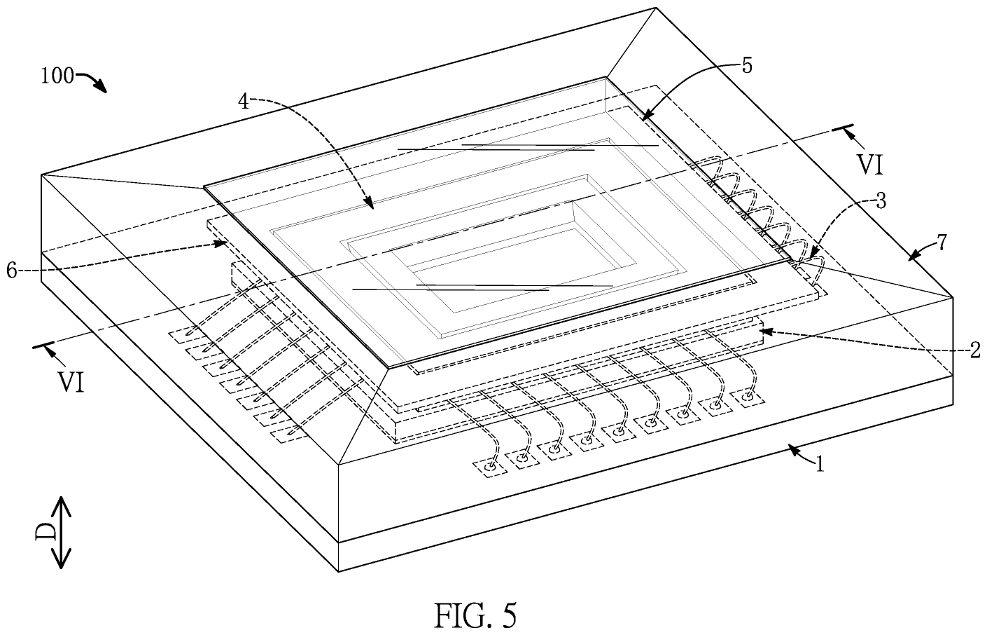

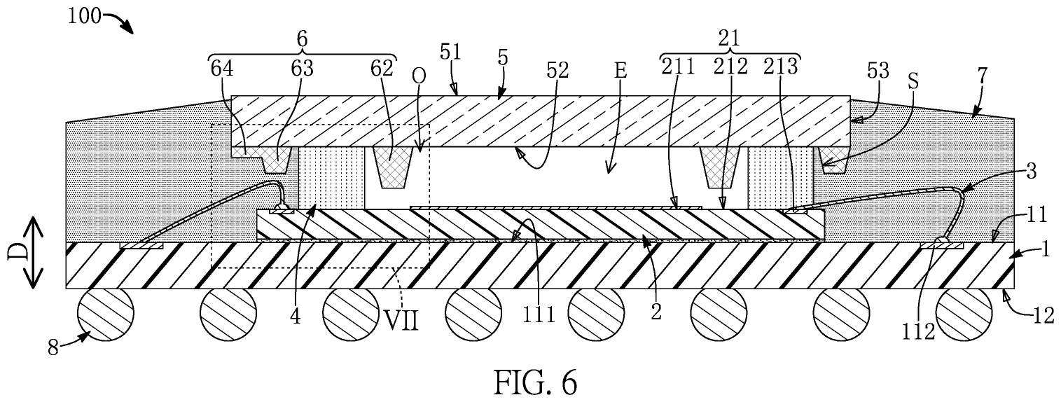

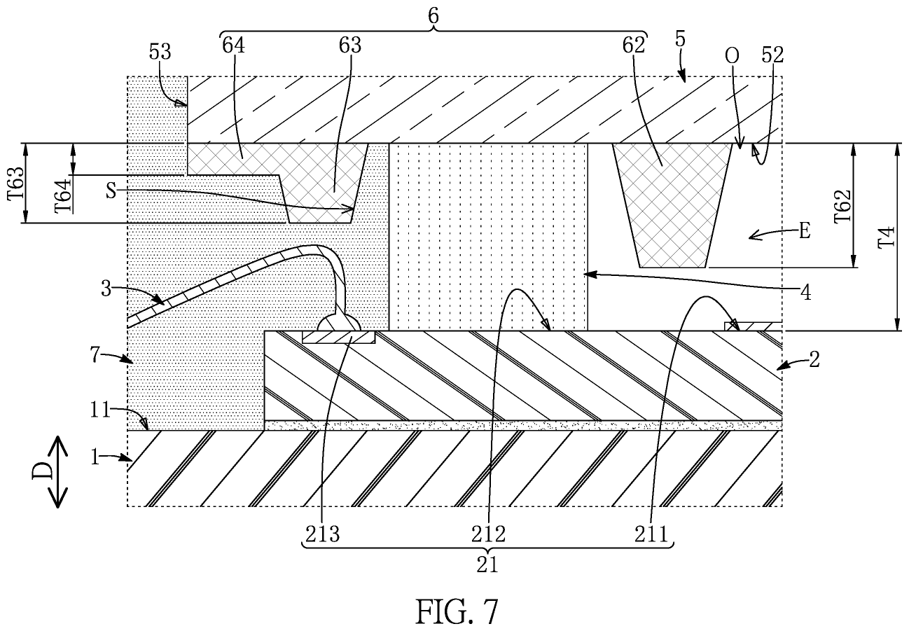

Referring to FIG. 5 to FIG. 8, a second embodiment of the present disclosure, which is similar to the first embodiment of the present disclosure, is provided. For the sake of brevity, descriptions of the same components in the first and second embodiments of the present disclosure (e.g., the substrate 1, the sensor chip 2, the metal wires 3, the supporting layer 4, the light-permeable layer 5, and the encapsulant 7) will be omitted herein, and the following description only discloses different features between the first and second embodiments.

In the present embodiment, as shown in FIG. 5 to FIG. 7, the grooved shielding layer 6 does not have the connection segment 61 of the first embodiment (as shown in FIG. 2), so that the inner barrier 62 and the outer barrier 63 are cooperated with a part of the lower surface 52 of the light-permeable layer 5 arranged therebetween for jointly forming the ring-shaped groove S. The light-permeable layer 5 is disposed on the supporting layer 4 through the part of the lower surface 52 thereof (e.g., the supporting layer 4 is sandwiched between the light-permeable layer 5 and the sensor chip 2), so that a part of the supporting layer 4 is arranged in the ring-shaped groove S. Moreover, the enclosed space E is surroundingly defined by the light-permeable layer 5, the supporting layer 4, and the sensor chip 2, and the inner barrier 62 is located in the enclosed space E.

The supporting layer 4 in the present embodiment is directly in contact with the light-permeable layer 5, so that the supporting layer 4 can receive light passing through the light-permeable layer 5. Accordingly, the supporting layer 4 can be made of a light-curing material (e.g., a UV curing material), thereby reducing the degree of heating of the air in the enclosed space E.

It should be noted that in order to enable the grooved shielding layer 6 to have a better anti-glare effect and in order to effectively prevent the supporting layer 4 from being deformed outwardly (or having an offset) due to the air in the enclosed space E expanding and pushing the supporting layer 4 outward when heated, the inner barrier 62 and the outer barrier 63 are preferably provided with at least part of the following features, but the present disclosure is not limited thereto.

At least one of the inner barrier 62 and the outer barrier 63 has a frustum shape that tapers in the predetermined direction D toward the sensor chip 2, but the present disclosure is not limited thereto. Specifically, along the predetermined direction D, the thickness T62 of the inner barrier 62 is within a range from 50% to 300% of the thickness T63 of the outer barrier 63, the thickness T62 of the inner barrier 62 is preferably within a range from 30% to 50% of the supporting thickness T4, and the thickness T63 of the outer barrier 63 is also within a range from 30% to 50% of the supporting thickness T4, but the thicknesses can be adjusted or changed according to design requirements.

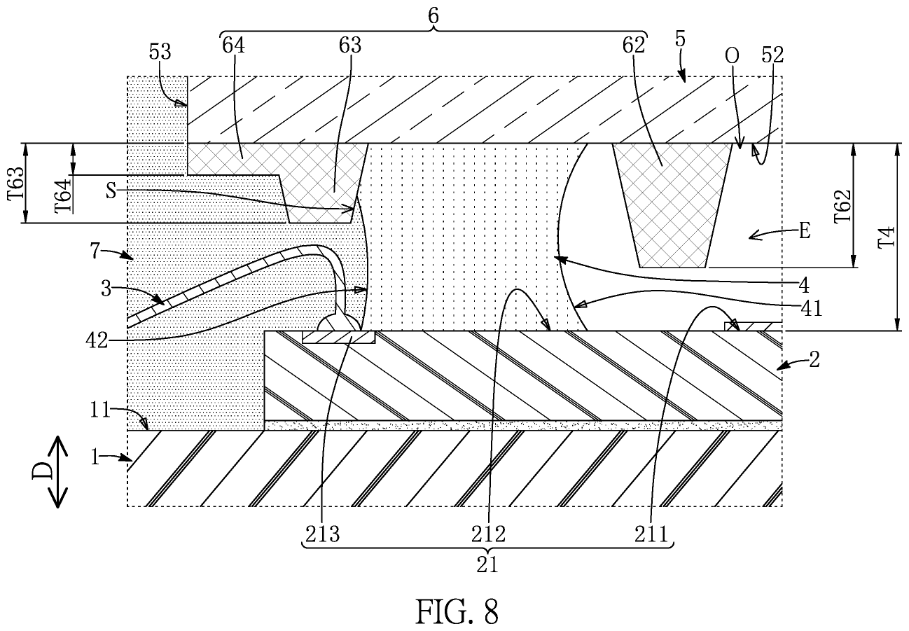

Specifically, as shown in FIG. 8, when the supporting layer 4 is outwardly deformed or has the offset, the outer barrier 63 can be used to limit the offset by blocking the supporting layer 4 from being outwardly deformed any further, so that an area of the inner barrier 62 connected to the supporting layer 4 is less than an area of the outer barrier 63 connected to the supporting layer 4. Moreover, the radius of curvature of the inner arced surface 41 is less than the radius of curvature of the outer arced surface 42. The center of curvature of the inner arced surface 41 can be substantially located in the enclosed space E, and the center of curvature of the outer arced surface 42 is located outside of the sensor package structure 100.

### Beneficial Effects of the Embodiments

In conclusion, the sensor package structure of the present disclosure is provided with the structural cooperation between the supporting layer and the grooved shielding layer so as to simultaneously have a plurality of technical effects, such as the grooved shielding layer being capable of blocking a visible light from passing therethrough so as to reduce the glare phenomenon that is generated by the visible light reflected from the supporting layer, and the grooved shielding layer being capable of limiting an offset of the supporting layer by blocking the supporting layer from being outwardly deformed any further, thereby avoiding a peeling issue of the light-permeable layer.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
a sensor chip disposed on the substrate along a predetermined direction and electrically coupled to the substrate, wherein a top surface of the sensor chip includes a sensing region and a carrying region that surrounds the sensing region;
a supporting layer being ring-shaped and being disposed on the carrying region of the sensor chip;
a light-permeable layer having an upper surface and a lower surface that is opposite to the upper surface, wherein the light-permeable layer is arranged above the sensor chip through the supporting layer, and the sensing region faces toward the light-permeable layer; and
a grooved shielding layer being ring-shaped, wherein the grooved shielding layer is disposed on the lower surface of the light-permeable layer for blocking a visible light from passing therethrough, and the grooved shielding layer includes:
an inner barrier located at an inner side of the supporting layer;
an outer barrier located at an outer side of the supporting layer; and
a connection segment that is connected to the inner barrier and the outer barrier so as to jointly form a ring-shaped groove, wherein the grooved shielding layer is disposed on the supporting layer through the connection segment, so that a part of the supporting layer is arranged in the ring-shaped groove;
wherein an inner edge of the inner barrier has an opening located directly above the sensing region, and wherein the grooved shielding layer, the light-permeable layer, the supporting layer, and the sensor chip jointly define an enclosed space, and the inner barrier is arranged in the enclosed space.

2. The sensor package structure according to claim 1, wherein the supporting layer has a supporting thickness along the predetermined direction, and the inner barrier has a thickness along the predetermined direction, and wherein the thickness is within a range from 10% to 30% of the supporting thickness.

3. The sensor package structure according to claim 1, wherein the supporting layer has a supporting thickness along the predetermined direction, and the outer barrier has a thickness along the predetermined direction, and wherein the thickness is within a range from 10% to 30% of the supporting thickness.

4. The sensor package structure according to claim 1, wherein along the predetermined direction, a thickness of the inner barrier is within a range from 50% to 300% of a thickness of the outer barrier.

5. The sensor package structure according to claim 1, wherein along the predetermined direction, a thickness of the connection segment is within a range from 10% to 80% of a thickness of the inner barrier.

6. The sensor package structure according to claim 1, wherein the supporting layer has an inner arced surface and an outer arced surface, and a radius of curvature of the inner arced surface is less than a radius of curvature of the outer arced surface.

7. The sensor package structure according to claim 1, wherein an area of the inner barrier connected to the supporting layer is less than an area of the outer barrier connected to the supporting layer.

8. The sensor package structure according to claim 1, wherein the grooved shielding layer includes an extension segment connected to the outer barrier, and an edge of the extension segment is flush with a surrounding lateral surface of the light-permeable layer.

9. The sensor package structure according to claim 1, wherein an edge of the outer barrier is flush with a surrounding lateral surface of the light-permeable layer.

10. The sensor package structure according to claim 1, wherein at least one of the inner barrier and the outer barrier has a frustum shape that tapers in the predetermined direction toward the sensor chip.

11. A sensor package structure, comprising:
a substrate;
a sensor chip disposed on the substrate along a predetermined direction and electrically coupled to the substrate, wherein a top surface of the sensor chip includes a sensing region and a carrying region that surrounds the sensing region;
a supporting layer being ring-shaped and being disposed on the carrying region of the sensor chip;
a light-permeable layer having an upper surface and a lower surface that is opposite to the upper surface, wherein the light-permeable layer is arranged above the sensor chip through the supporting layer, and the sensing region faces toward the light-permeable layer; and
a grooved shielding layer being ring-shaped, wherein the grooved shielding layer is disposed on the lower surface of the light-permeable layer for blocking a visible light from passing therethrough, and the grooved shielding layer includes:
an inner barrier located at an inner side of the supporting layer; and
an outer barrier located at an outer side of the supporting layer, wherein the inner barrier, the outer barrier, and a part of the lower surface of the light-permeable layer jointly form a ring-shaped groove, and wherein the light-permeable layer is disposed on the supporting layer through the part of the lower surface thereof, so that a part of the supporting layer is arranged in the ring-shaped groove;
wherein an inner edge of the inner barrier has an opening located directly above the sensing region, and wherein the light-permeable layer, the supporting layer, and the sensor chip jointly define an enclosed space, and the inner barrier is arranged in the enclosed space.

12. The sensor package structure according to claim 11, wherein the supporting layer has a supporting thickness along the predetermined direction, and the inner barrier has a thickness along the predetermined direction, and wherein the thickness is within a range from 30% to 50% of the supporting thickness.

13. The sensor package structure according to claim 11, wherein the supporting layer has a supporting thickness along the predetermined direction, and the outer barrier has a thickness along the predetermined direction, and wherein the thickness is within a range from 30% to 50% of the supporting thickness.

14. The sensor package structure according to claim 11, wherein along the predetermined direction, a thickness of the inner barrier is within a range from 50% to 300% of a thickness of the outer barrier.

15. The sensor package structure according to claim 11, wherein the supporting layer has an inner arced surface and an outer arced surface, and a radius of curvature of the inner arced surface is less than a radius of curvature of the outer arced surface.

16. The sensor package structure according to claim 11, wherein an area of the inner barrier connected to the supporting layer is less than an area of the outer barrier connected to the supporting layer.

17. The sensor package structure according to claim 11, wherein the grooved shielding layer includes an extension segment connected to the outer barrier, and an edge of the extension segment is flush with a surrounding lateral surface of the light-permeable layer.

18. The sensor package structure according to claim 11, wherein an edge of the outer barrier is flush with a surrounding lateral surface of the light-permeable layer.

19. The sensor package structure according to claim 11, wherein at least one of the inner barrier and the outer barrier has a frustum shape that tapers in the predetermined direction toward the sensor chip.

20. The sensor package structure according to claim 11, further comprising an encapsulant formed on the substrate, wherein the sensor chip, the supporting layer, the light-permeable layer, and the grooved shielding layer are embedded in the encapsulant, and at least part of the upper surface of the light-permeable layer is exposed from the encapsulant, and wherein a part of the ring-shaped groove between the supporting layer and the outer barrier is filled with the encapsulant.
